(19) United States
(12) Patent Application Publication
(10) Pub. No.: US 2013/0240900 A1
(43) Pub. Date: Sep. 19, 2013

(54) SEMICONDUCTOR DEVICE AND METHOD FOR PRODUCING THE SAME

(71) Applicants: Seiji Yaegashi, Tokyo (JP); Makoto Kiyama, Itami-shi (JP); Kazutaka Inoue, Yokohama-shi (JP); Mitsunori Yokoyama, Tokyo (JP); Yu Saitoh, Itami-shi (JP); Masaya Okada, Osaka-shi (JP)

(72) Inventors: Seiji Yaegashi, Tokyo (JP); Makoto Kiyama, Itami-shi (JP); Kazutaka Inoue, Yokohama-shi (JP); Mitsunori Yokoyama, Tokyo (JP); Yu Saitoh, Itami-shi (JP); Masaya Okada, Osaka-shi (JP)

(73) Assignee: SUMITOMO ELECTRIC INDUSTRIES, LTD., Osaka-shi (JP)

(21) Appl. No.: 13/883,526

(22) PCT Filed: Oct. 17, 2011
(86) PCT No.: PCT/JP2011/073826

§ 371 Date: May 3, 2013

(30) Foreign Application Priority Data
Nov. 4, 2010 (JP) 2010-247719

(51) Int. Cl. H01L 29/20; H01L 21/265; H01L 21/22

(52) U.S. Cl. CPC H01L 29/2003; H01L 21/22; H01L 21/265
USPC 257/76; 438/510; 438/514

(57) ABSTRACT

There is provided a semiconductor device or the like which includes a channel and a gate electrode in an opening and in which electric field concentration near a bottom portion of the opening can be reduced. The semiconductor device includes n⁻-type GaN drift layer 4/p-type GaN barrier layer 6/n⁺-type GaN contact layer. An opening 28 extends from the top layer and reaches the n-type GaN-based drift layer. The semiconductor device includes a regrown layer 27 located in the opening, the regrown layer 27 including an electron supply layer 26 and an electron drift layer 22, a source electrode S, a drain electrode D, a gate electrode G located on the regrown layer, and a semiconductor impurity adjustment region 31 disposed in the bottom portion of the opening. The impurity adjustment region 31 is a region that promotes a potential drop from the drain electrode side to the gate electrode side in a potential distribution in an off-state.

### TECHNICAL FIELD

The present invention relates to a semiconductor device used for high power switching and a method for producing the semiconductor device, and particularly to a semiconductor device that uses a GaN-based semiconductor among nitride-based semiconductors and a method for producing the semiconductor device.

### BACKGROUND ART

High reverse breakdown voltage and low on-resistance are required for high current switching devices. Field effect transistors (FETs) that use a group III nitride-based semiconductor are excellent in terms of, for example, high breakdown voltage and high-temperature operation because of their wide band gap. Therefore, vertical transistors that use a GaN-based semiconductor have been particularly receiving attention as transistors for controlling high power. For example, PTL 1 proposes a vertical GaN-based FET whose mobility is increased and whose on-resistance is decreased by forming an opening in a GaN-based semiconductor and forming a regrown layer including a channel of two-dimensional electron gas (2DEG) in the opening. In this vertical GaN-based FET, a structure including a p-type GaN barrier layer and the like is proposed in order to improve the breakdown voltage characteristics and pinch-off characteristics.

### CITATION LIST

### Patent Literature

PTL 1: Japanese Unexamined Patent Application Publication No. 2006-286942

### SUMMARY OF INVENTION

### Technical Problem

In the above vertical GaN-based FET, the breakdown voltage characteristics may be improved by a depletion layer formed in a pn junction between the p-type GaN barrier layer and an n⁻-type GaN drift layer. However, the opening penetrates through the p-type GaN barrier layer and reaches the n⁻-type GaN drift layer. Therefore, a gate electrode G faces a drain electrode without the p-type GaN barrier layer disposed therebetween. When the semiconductor device is used as a high-power switching device, a voltage of several hundred volts to one thousand and several hundred volts is applied between the source electrode (ground) and the drain electrode in the off-state. A voltage of about minus several volts is applied to the gate electrode in the off-state. Because of the high source-drain voltage, electric field concentration is generated in the bottom portion of the opening, in particular, in a portion of the n⁻-type GaN drift layer near a ridge (corner in a sectional view) of the bottom portion. As a result, breakdown of a semiconductor occurs from an uneven portion or the like inevitably provided by the ridge of the bottom portion of the opening. The breakdown voltage characteristics in the off-state in the bottom portion of the opening cannot be sufficiently ensured by the above-described p-type barrier layer.

It is an object of the present invention to provide a vertical semiconductor device having an opening and including a channel and a gate electrode in the opening. In the semiconductor device, the electric field concentration near the bottom portion of the opening can be reduced in the off-state. It is another object of the present invention to provide a method for producing the semiconductor device.

### Solution to Problem

A semiconductor device of the present invention is a vertical semiconductor device including a GaN-based stacked layer having an opening. In this semiconductor device, the GaN-based stacked layer includes n-type GaN-based drift layer/p-type GaN-based barrier layer/n-type GaN-based contact layer in that order to the top layer side and the opening extends from a top layer and reaches the n-type GaN-based drift layer. The semiconductor device includes a regrown layer located so as to cover a wall surface of the opening, the regrown layer including an electron drift layer and an electron supply layer; a source electrode that is in contact with the n-type GaN-based contact layer and the regrown layer; a drain electrode located so as to face the source electrode with the GaN-based stacked layer sandwiched therebetween; a gate electrode located on the regrown layer; and a semiconductor impurity adjustment region disposed in a bottom portion of the opening. The impurity adjustment region is a region that promotes a potential drop from the drain electrode side to the gate electrode side in a potential distribution in an off-state.

In the vertical semiconductor device, a high voltage of several hundred volts to one thousand and several hundred volts is applied between the source electrode disposed on one principal surface (a top surface of the GaN-based semiconductor layer) and the drain electrode that faces the source electrode with the GaN-based semiconductor layer sandwiched therebetween. The source electrode is fixed at a ground potential and a high voltage is applied to the drain electrode. The gate electrode is held at minus several volts, such as −5 V, in the off-state for the purpose of opening and closing the channel. That is, in the off-state, the gate electrode has a minimum potential. The voltage difference between the gate electrode and the drain electrode is 5 V higher than the voltage difference between the source electrode and the drain electrode.

According to the above structure, the impurity adjustment region promotes a potential drop from the drain electrode side to the gate electrode side in a potential distribution in an off-state. This decreases the potential difference in the off-state between a semiconductor located in the bottom portion of the opening and the gate electrode. Therefore, a high degree of electric field concentration that has been generated in existing semiconductor devices is not generated in the off-state. Even if a high voltage is applied between the drain electrode and the gate electrode, the electric field concentration in a semiconductor such as the n-type GaN-based drift layer in the bottom portion of the opening is reduced. In particular, the electric field concentration near a ridge (corner in a sectional view) at which the bottom portion of the opening and the wall surface of the opening intersect each other is reduced. Consequently, the breakdown of a semiconductor near the ridge does not readily occur.

Regarding the conductivity type, n-type or p-type, the concentration of an impurity is not limited and may be any concentration from low concentration to high concentration.

The impurity adjustment region can be a region formed by dividing the n-type GaN-based drift layer into a plurality of layers and setting an n-type impurity concentration in one of said plurality of layers to be lower than those in other layers.

In the potential distribution in the off-state in a region from the drain electrode to the gate electrode, a voltage drop is promoted to a greater degree in a region in which the n-type impurity concentration is low than in a region in which the n-type impurity concentration is high. As a result, the potential difference in the off-state between the semiconductor located in the bottom portion of the opening and the gate electrode can be decreased. Furthermore, an increase in on-resistance can be suppressed by disposing a region in which the n-type impurity concentration is low at a position at which electron flow is expanded from the opening toward the drain electrode, that is, at a position closer to the drain electrode.

The n-type GaN-based drift layer can be divided into a second n-type drift layer that forms the bottom portion of the opening and a first n-type drift layer located on the drain electrode side of the second n-type drift layer, and an n-type impurity concentration in the second n-type drift layer can be set to be lower than that in the first n-type drift layer.

By setting the n-type impurity concentration in the second n-type drift layer located closer to the bottom portion of the opening to be low, the voltage drop in the second n-type drift layer is promoted, which can decrease the potential difference between the semiconductor in the bottom portion of the opening and the gate electrode. Consequently, the electric field concentration near the bottom portion of the opening and near the edge (corner or ridge) of the bottom portion is reduced.

The impurity adjustment region can be a bottom p-type region disposed in the bottom portion of the opening so as not to obstruct flow of electrons from the regrown layer. A pn junction can be formed between the bottom p-type region and the n-type GaN-based drift layer located below the bottom p-type region.

According to this, the potential difference between the gate electrode and the semiconductor located above the bottom p-type region can be decreased due to the voltage drop caused by a potential barrier formed in the pn junction and the voltage drop in a depletion layer formed in the pn junction. As a result, the electric field concentration near the bottom portion of the opening, in particular, near the corner can be reduced, which can prevent the breakdown of a semiconductor.

The bottom p-type region can be any one of (1) a plate-shaped bottom region having a plate-like shape and located below the regrown layer that covers the bottom portion of the opening, (2) a ring-shaped bottom region located below the regrown layer that covers the bottom portion of the opening and only at an edge of the bottom portion, and (3) a regrown layer bottom region formed by doping the regrown layer that covers the bottom portion of the opening with a p-type impurity.

According to this, by selecting a suitable bottom p-type region among the above bottom p-type regions in accordance with the usage of the semiconductor device in consideration of on-resistance or the like, the electric field concentration in the bottom portion of the opening, in particular, at the corner can be reduced while at the same time other characteristics can be satisfied.

The plate-like shape and ring shape may have any sectional shape, such as a disc-like shape and an annular shape or an angular plate-like shape and an angular ring shape.

In a method for producing a semiconductor of the present invention, a vertical semiconductor device including a GaN-based stacked layer having an opening is produced. The production method includes a step of forming a GaN-based stacked layer including n-type GaN-based drift layer/p-type GaN-based barrier layer/n-type GaN-based contact layer in that order to the top layer side; a step of forming an opening that extends from the n-type GaN-based contact layer and reaches the n-type GaN-based drift layer; and a step of forming a regrown layer so as to cover a wall surface and a bottom portion of the opening, the regrown layer including an electron drift layer and an electron supply layer. In the step of forming the GaN-based stacked layer, the n-type GaN-based drift layer is formed by successively growing a plurality of layers, and an n-type impurity concentration in one of said plurality of layers is set to be lower than those in other layers.

According to this method, a semiconductor device in which electric field concentration in the bottom portion of the opening is reduced can be produced in a simple manner using existing production equipment only by making a minor change in the process. The reason why the electric field concentration in the bottom portion of the opening is reduced is that, in the potential distribution in the off-state, a potential drop in an n-type region having a low n-type impurity concentration is large.

In the step of forming the GaN-based stacked layer, when the n-type GaN-based drift layer is grown, a first n-type drift layer is grown and then a second n-type drift layer is grown on the first n-type drift layer. An n-type impurity concentration in the second n-type drift layer can be set to be lower than that in the first n-type drift layer.

According to this, the voltage drop in the off-state in the second GaN drift layer can be increased by setting the n-type impurity concentration in the second GaN drift layer that forms the bottom portion of the opening to be low. Thus, the electric field concentration in the bottom portion of the opening, in particular, at the corner can be reduced.

In another method for producing a semiconductor device of the present invention, a vertical semiconductor device including a GaN-based stacked layer having an opening is produced. The production method includes a step of forming a GaN-based stacked layer including n-type GaN-based drift layer/p-type GaN-based barrier layer/n-type GaN-based contact layer in that order to the top layer side; a step of forming an opening that extends from the n-type GaN-based contact layer and reaches the n-type GaN-based drift layer; a step of forming a regrown layer so as to cover a wall surface and a bottom portion of the opening, the regrown layer including an electron drift layer and an electron supply layer; and a step of forming a resist pattern that covers a portion other than a bottom portion of the regrown layer and performing ion implantation with a p-type impurity to convert the bottom portion of the regrown layer into a p-type bottom portion.

According to this method, a semiconductor device in which electric field concentration in the bottom portion of the opening can be reduced can be produced by making a minor change in existing methods for producing a semiconductor device in which a channel is formed of two-dimensional electron gas in the opening. In other words, the electric field concentration can be reduced by forming the regrown layer bottom region obtained by converting the regrown layer in the bottom portion of the opening into a p-type regrown layer.

Before the step of forming the regrown layer and after the opening is formed, a resist pattern that covers a portion other than the bottom portion of the opening is formed and then ion implantation with a p-type impurity is performed in the bottom portion of the opening to form a bottom p-type region, or the bottom portion of the opening is removed by etching and embedded growth of a p-type layer is performed in the bottom portion to form a bottom p-type region; then the regrown layer is formed; and the following step of performing ion implantation with a p-type impurity is not conducted.

According to this method, the p-type region can be relatively easily formed in the bottom portion of the opening below the regrown layer. The shape of the p-type region may be selected from a plate-like shape and a ring shape in accordance with, for example, the usage of the semiconductor device.

### Advantageous Effects of Invention

According to the semiconductor device of the present invention, in a vertical semiconductor device having an opening and including a channel and a gate electrode in the opening, the electric field concentration in the off-state in the bottom portion of the opening can be reduced.

### BRIEF DESCRIPTION OF DRAWINGS

FIG. 1 is a sectional view showing a vertical GaN-based FET (semiconductor device) according to a first embodiment of the present invention (a sectional view taken along line I-I of FIG. 2).

FIG. 2 is a plan view of the vertical GaN-based FET in FIG. 1.

FIG. 3 is a diagram showing a method for producing the vertical GaN-based FET in FIG. 1, the diagram showing the state in which an epitaxial stacked layer including layers up to a contact layer has been formed on a substrate including a GaN layer that is in ohmic contact with a support substrate.

FIG. 4 is a diagram showing the state in which an opening has been formed by etching.

FIG. 5A is a diagram showing the state in which, at the stage of forming an opening by RIE, a resist pattern has been formed.

FIG. 5B is a diagram showing the state in which, at the stage of forming an opening by RIE, the stacked layer is etched down by performing ion irradiation and an opening is expanded (caused to recede).

FIG. 6 is a diagram showing the state in which a regrown layer has been formed in the opening.

FIG. 7 is a diagram showing the state in which an insulating layer has been grown on the regrown layer.

FIG. 8 is a sectional view of a semiconductor device that belongs to the first embodiment of the present invention, which is a modification of the semiconductor device in FIG. 1.

FIG. 9 is a sectional view showing a vertical GaN-based FET (semiconductor device) according to a second embodiment of the present invention.

FIG. 10 is a sectional view of a semiconductor device that belongs to the second embodiment of the present invention, which is modification 1 of the semiconductor device in FIG. 9.

FIG. 11 is a sectional view of a semiconductor device that belongs to the second embodiment of the present invention, which is modification 2 of the semiconductor device in FIG. 9.

FIG. 12 is a diagram showing the effect of varied n-type impurity concentrations in a second GaN drift layer on the maximum electric field strength in a bottom portion of an opening in Examples. All test specimens have the same n-type impurity concentration in a first GaN drift layer 4a, which is 1×10¹⁶ (1E16) cm ⁻³.

### REFERENCE SIGNS LIST

1 GaN substrate

4 n⁻-type GaN drift layer

4a first GaN drift layer

4b second GaN drift layer

4c third GaN drift layer

6 p-type GaN barrier layer

7 n⁺-type GaN contact layer

9 insulating layer

10 semiconductor device (vertical GaN-based FET)

12 gate wiring line

13 gate pad

15 GaN-based stacked layer

22 GaN electron drift layer

26 AlGaN electron supply layer

27 regrown layer

28 opening

28a wall surface of opening

28b bottom portion of opening

31 bottom p-type region (plate-shaped p-type region, ring-shaped p-type region, or regrown layer p-type region)

D drain electrode

G gate electrode

K ridge or corner of opening

M1 resist pattern

S source electrode

### DESCRIPTION OF EMBODIMENTS

### First Embodiment

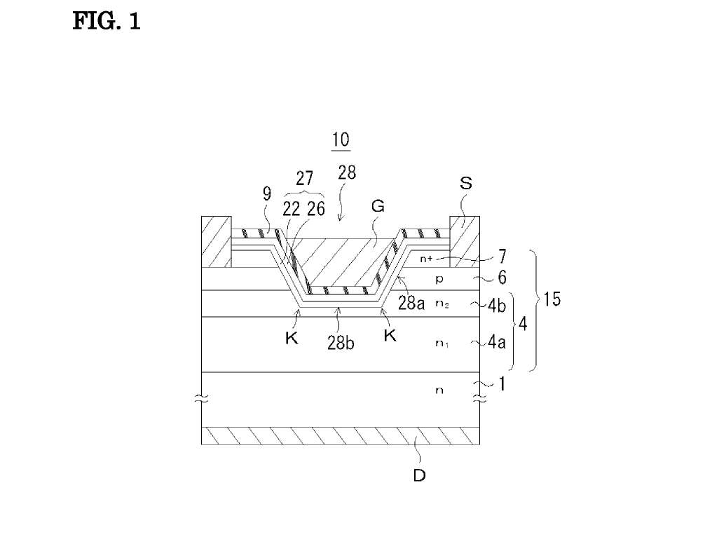

FIG. 1 is a sectional view of a vertical GaN-based FET (semiconductor device) 10 according to a first embodiment of the present invention. The vertical GaN-based FET 10 includes a conductive GaN substrate 1 and n⁻-type GaN drift layer 4/p-type GaN barrier layer 6/n⁺-type GaN contact layer 7 epitaxially grown on the GaN substrate 1. The n⁻-type GaN drift layer 4 includes a first GaN drift layer 4a located on the substrate side and a second GaN drift layer 4b that forms a bottom portion 28b of an opening. The n-type impurity concentration n₂ in the second GaN drift layer 4b is lower than the n-type impurity concentration n₁ in the first GaN drift layer 4a. The feature of the semiconductor device 10 of this embodiment is that the n⁻-type GaN drift layer 4 is divided into two layers and the n-type impurity concentration n₂ in the second GaN drift layer that forms the bottom portion 28b of the opening 28 is low as described above. The condition that the n-type impurity concentration n₂ in the second GaN drift layer 4b is lower than the n-type impurity concentration n₁ in the first GaN drift layer 4a only applies to the impurity concentration in the n⁻-type GaN drift layer 4. Obviously, the n-type impurity concentration n₂ is lower than the n-type impurity concentration in an existing n⁻-type GaN drift layer 4. The effects achieved by this feature will be described later.

The n⁻-type GaN drift layer 4 (first and second GaN drift layers 4a and 4b)/p-type GaN barrier layer 6/n⁺-type GaN contact layer 7 is successively formed to constitute a GaN-based stacked layer 15. A buffer layer composed of an AlGaN layer or GaN layer may be inserted between the GaN substrate 1 and the n⁻-type GaN drift layer 4 depending on the type of the GaN substrate 1.

The GaN substrate 1 may be a so-called monolithic, thick GaN substrate or a substrate including a GaN layer that is in ohmic contact with a support substrate. In addition, by forming a GaN layer on a GaN substrate or the like during the growth of a GaN-based stacked layer and then removing a portion having a certain thickness corresponding to the thickness of the GaN substrate or the like, only a thin GaN layer may be left as a base in the form of products. The GaN substrate, the substrate including a GaN layer that is in ohmic contact with a support substrate, and the thin GaN layer left as a base in the form of products may be simply referred to as a GaN substrate.

The thin GaN layer left as a base may be a conductive or nonconductive layer and a drain electrode can be disposed on the top or bottom surface of the thin GaN layer depending on the production process and the structure of products. In the case where the GaN substrate, the support substrate, or the like is left in a product, the support substrate or the substrate may be a conductive or nonconductive substrate. When the support substrate or the substrate is a conductive substrate, the drain electrode can be disposed directly on the bottom (lower) surface or top (upper) surface of the support substrate or the substrate. When the support substrate or the substrate is a nonconductive substrate, the drain electrode can be disposed above the nonconductive substrate and on a conductive layer located on the lower layer side in the semiconductor layers.

In this embodiment, the p-type GaN barrier layer 6 is used as the p-type GaN-based barrier layer, but any layer composed of a p-type GaN-based semiconductor, such as a p-type AlGaN layer, may be used.

Regarding other layers constituting the stacked layer 15, other GaN-based semiconductor layers may be used instead of the GaN layers described above, if necessary.

In the GaN-based stacked layer 15, an opening 28 is formed so as to penetrate from the n⁺-type GaN contact layer 7 to the p-type GaN barrier layer 6 and reach the n⁻-type GaN drift layer 4. The opening 28 is defined by a wall surface (side surface) 28a and the bottom portion 28b. A regrown layer 27 is epitaxially grown so as to cover the wall surface 28a and bottom portion 28b of the opening 28 and the top layer (n⁺-type GaN contact layer 7) of the GaN-based stacked layer 15. The regrown layer 27 is constituted by an insulating GaN (i-type GaN) electron drift layer 22 and an AlGaN electron supply layer 26. An intermediate layer composed of AlN or the like may be inserted between the i-type GaN electron drift layer 22 and the AlGaN electron supply layer 26. A source electrode S is located on the GaN-based stacked layer 15 so as to be electrically connected to the regrown layer 27, the n⁺-type contact layer 7, and the p-type GaN barrier layer 6. In FIG. 1, the source electrode S extends downwards and has a side surface that is in contact with the end face of the regrown layer 27 and the n⁺-type contact layer 7 and an end portion that is in contact with the p-type GaN barrier layer 6. Thus, an electrical connection is established. A drain electrode D is located on the bottom surface of the GaN substrate 1.

An insulating layer 9 is located below a gate electrode G so as to cover the regrown layer 27. The insulating layer 9 is disposed in order to reduce a gate leak current generated when positive voltage is applied to the gate electrode, which allows high-current operation. Since the threshold voltage can be further shifted in a positive direction, normally-off is easily achieved. Note that the insulating layer 9 is not necessarily disposed.

In the on-state, in the regrown layer 27, two-dimensional electron gas (2DEG) is generated in the i-type GaN electron drift layer 22 at a position near the interface between the i-type GaN electron drift layer 22 and the AlGaN electron supply layer 26. Such two-dimensional electron gas is generated in the i-type GaN electron drift layer 22 at a position near the interface between the i-type GaN electron drift layer 22 and the AlGaN electron supply layer due to, for example, spontaneous polarization or piezoelectric polarization caused by difference in lattice constant. Electrons flow from the source electrode S to the drain electrode D through the two-dimensional electron gas and the n⁻-type GaN drift layer 4. Since the i-type GaN electron drift layer 22 and the AlGaN electron supply layer 26 in the regrown layer 27 are successively grown in the same growth chamber, the density of impurity level or the like at the interface can be reduced to a low value. Therefore, a high current (per unit area) can be caused to flow with low on-resistance while having a structure in which a high current is caused to flow in a thickness direction by forming the opening 28.

As described above, in the off-state, a high voltage of several hundred volts to one thousand and several hundred volts is applied between the source electrode S held at a ground potential and the drain electrode D. The gate electrode is held at minus several volts, such as −5 V, in the off-state for the purpose of opening and closing the channel. In the off-state, the gate electrode has a minimum potential.

In the case where the n⁻-type GaN drift layer 4 has a single layer structure as in existing vertical semiconductor devices, the n-type impurity concentration needs to be kept at a certain concentration to achieve low on-resistance. Therefore, in the potential distribution in the off-state in a region from the drain electrode D to the bottom portion of the opening 28, a voltage drop in the n⁻-type GaN drift layer 4 is not so large. As a result, a large potential difference is held between the gate electrode and the semiconductor 4 near the bottom portion of the opening, which generates high electric field concentration at the semiconductor near the bottom portion 28b of the opening, in particular, at a corner K.

In contrast, in the semiconductor device 10 of this embodiment, the n⁻-type GaN drift layer 4 is divided into two layers, and the n-type impurity concentration n₂ in the second GaN drift layer 4b that forms the bottom portion 28b of the opening is set to be lower than the n-type impurity concentration n₁ in the first GaN drift layer 4a located on the substrate side as described above. The n-type impurity concentrations n₁ and n₂ both fall under the category of n⁻-type (low concentration) indicated by the n⁻-type GaN drift layer 4. In particular, the n-type impurity concentration n₂ in the second GaN drift layer 4b is set to be lower than the n-type impurity concentration n₁ in the first GaN drift layer 4a. As a result, the voltage drop in the second GaN drift layer 4b becomes large in the potential distribution in the off-state. The specific n-type impurity concentrations and thicknesses of the first and second GaN drift layers 4a and 4b can be set in accordance with, for example, the required on-resistance.

The n-type impurity concentration n₂ in the second GaN drift layer 4b may be, for example, 1×10¹⁴ (1E14) cm⁻³ or more and 5×10¹⁶ (5E16) cm⁻³ or less and the thickness of the second GaN drift layer 4b may be, for example, 0.1 μm or more and 0.3 μm or less. The n-type impurity concentration n₁ in the first GaN drift layer 4a may be, for example, 5×10 ¹⁴ (5E14) cm⁻³ or more and 5×10¹⁷ (5E17) cm⁻³ or less and the thickness of the first GaN drift layer 4a may be, for example, 0.5 μm or more and 7 μm or less. The thickness of the second GaN drift layer 4b may be smaller than that of the first GaN drift layer 4a for the purpose of maintaining low on-resistance.

The p-type impurity concentration in the p-type GaN barrier layer 6 may be about 1×10¹⁷ (1E17) cm⁻³ to 1×10¹⁹ (1E19) cm⁻³. The p-type impurity may be an impurity, such as Mg, that forms an acceptor in a GaN-based semiconductor. The thickness of the p-type GaN barrier layer 6 is dependent on, for example, the thickness of the n⁻-type GaN drift layer, and thus the range of the thickness cannot be determined in a general manner. However, the typical thickness often used in many devices is about 0.3 μm to 1 μm. If the thickness is less than 0.3 μm, breakdown voltage characteristics and pinch-off characteristics cannot be sufficiently produced and thus 0.3 μm may be set as the lower limit of thickness. If the p-type GaN barrier layer 6 having a thickness of about 0.3 μm to 1 μm has an excessively high Mg content, straight movement toward the end face of the p-type GaN barrier layer 6 occurs, which adversely affects the channel (increases the on-resistance). The reverse voltage characteristics (breakdown voltage characteristics) at a pn junction between the p-type GaN barrier layer 6 and the n⁻-type GaN drift layer during channel interruption (off-state) are also degraded.

The thickness of the n⁺-type GaN contact layer 7 may be about 0.1 μm to 0.6 μm. The length of the n⁺-type GaN contact layer 7 may be 0.5 μm or more and 5 μm or less.

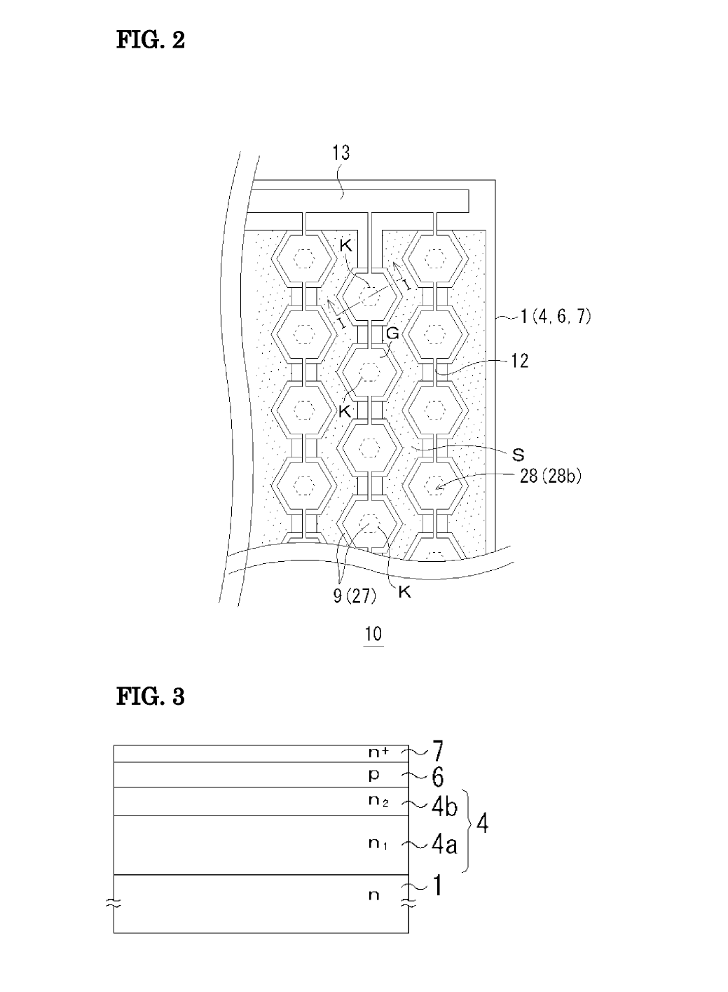

FIG. 2 is a plan view of the vertical GaN-based semiconductor device 10 shown in FIG. 1, and FIG. 1 is a sectional view taken along line I-I of FIG. 2. Referring to FIG. 2, the opening 28 has a hexagonal shape and a region around the opening 28 is substantially covered with the source electrode S while the source electrode S does not overlap a gate wiring line 12. Consequently, a closest-packed structure (honey-comb structure) is formed and thus the gate electrode has a long perimeter per unit area. By employing such a shape, the on-resistance can also be decreased. An electric current flows from the source electrode S and enters a channel (electron drift layer 22) in the regrown layer 27 directly or through the n⁺-type GaN contact layer 7. Then, the electric current flows to the drain electrode D through the second GaN drift layer 4b and the first GaN drift layer 4a. In order to prevent the source electrode S and the wiring line thereof from interfering with a gate structure including the gate electrode G, the gate wiring line 12, and a gate pad 13, the source wiring line is disposed on an interlayer-insulating layer (not shown). A via hole is formed in the interlayer-insulating layer, and the source electrode S including a conductive portion obtained by filling the via hole is conductively connected to a source conductive layer (not shown) on the interlayer-insulating layer. As a result, a source structure including the source electrode S can have low electrical resistance and high mobility, which are suitable for high-power devices.

The perimeter of openings per unit area can also be increased by densely arranging elongated openings instead of employing the hexagonal honey-comb structure. Consequently, the current density can be improved.

A method for producing the semiconductor device 10 according to this embodiment will be described. As shown in FIG. 3, a stacked layer 15 including n⁻-type GaN drift layer 4 (first GaN drift layer 4a and second GaN drift layer 4b)/p-type GaN barrier layer 6/n⁺-type GaN contact layer 7 is grown on a GaN substrate 1 corresponding to the above-described GaN substrate. A GaN-based buffer layer (not shown) may be inserted between the GaN substrate 1 and the n⁻-type GaN drift layer 4.

The formation of the above layers may be performed by, for example, metal-organic chemical vapor deposition (MOCVD). By performing growth using MOCVD, a stacked layer 15 having good crystallinity can be formed. In the case where the GaN substrate 1 is formed by growing a gallium nitride film on a conductive substrate using MOCVD, trimethylgallium is used as a gallium raw material. High-purity ammonia is used as a nitrogen raw material. Purified hydrogen is used as a carrier gas. The purity of the high-purity ammonia is 99.999% or more and the purity of the purified hydrogen is 99.999995% or more. A hydrogen-based silane may be used as a Si raw material for an n-type dopant (donor) and cyclopentadienyl magnesium may be used as a Mg raw material for a p-type dopant (acceptor).

A conductive GaN substrate having a diameter of two inches is used as the conductive substrate. The substrate is cleaned at 1030° C. at 100 Torr in an atmosphere of ammonia and hydrogen. Subsequently, the temperature is increased to 1050° C. and a gallium nitride layer is grown at 200 Torr at a V/III ratio of 1500, which is the ratio of the nitrogen raw material and gallium raw material. The formation method of the GaN layer on the conductive substrate is employed for not only the formation of the GaN substrate 1 but also the growth of the stacked layer 15 on the GaN substrate 1.

By employing the above-described method, the first GaN drift layer 4a/second GaN drift layer 4b/p-type GaN barrier layer 6/n⁺-type GaN contact layer 7 is grown on the GaN substrate 1 in that order.

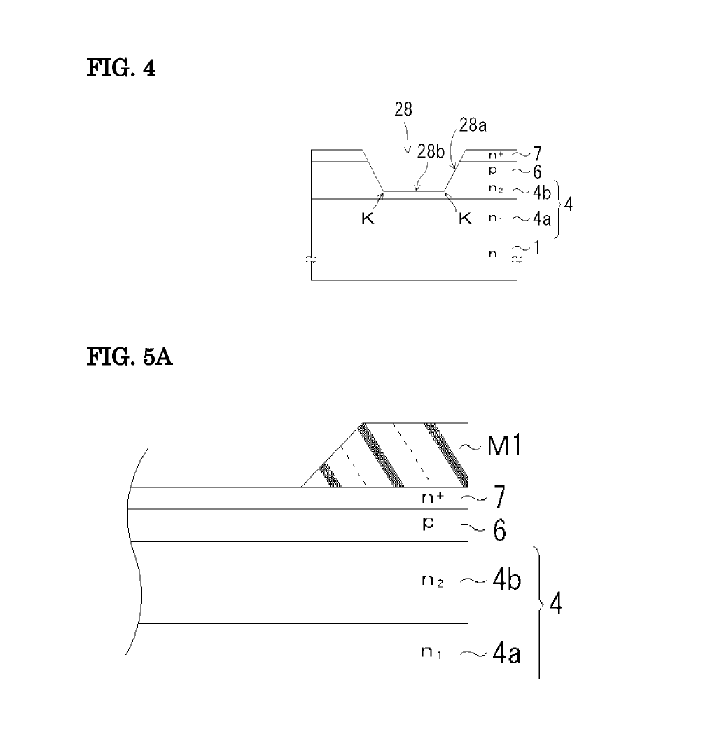

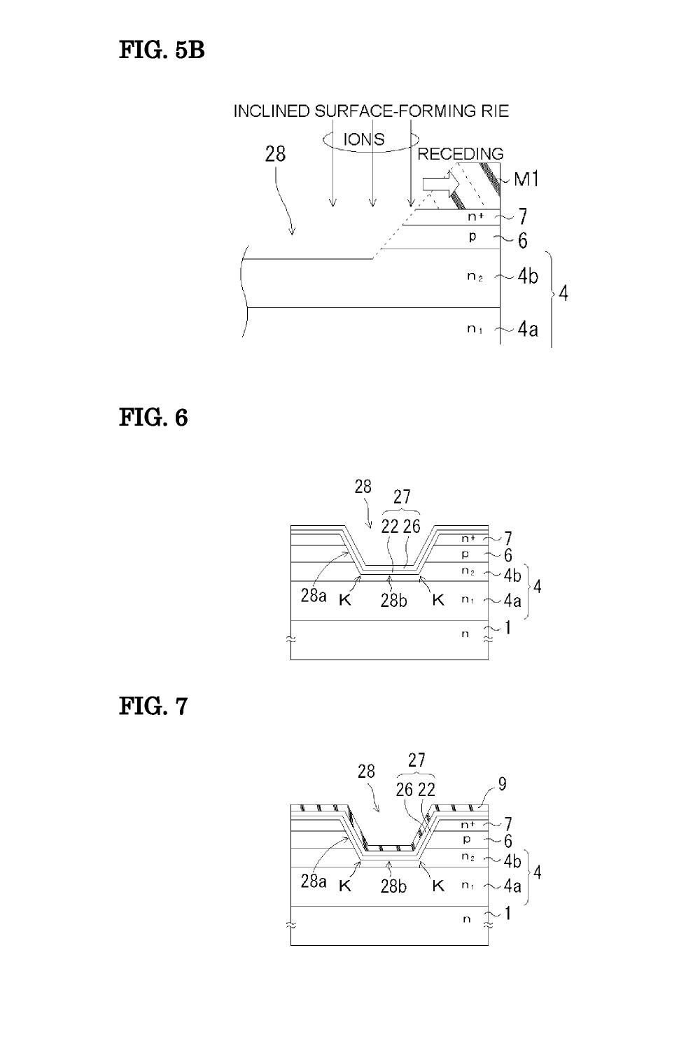

Subsequently, as shown in FIG. 4, an opening 28 is formed by reactive ion etching (RIE). As shown in FIGS. 5A and 5B, a resist pattern Ml is formed on the top of epitaxial layers 4, 6, and 7. The resist pattern Ml is then etched by RIE to cause the resist pattern M1 to recede, whereby an opening is expanded to form an opening 28. In this RIE process, the inclined surface of the opening 28, that is, the end face of the stacked layer 15 is damaged by being subjected to ion irradiation. In the damaged portion, for example, a high-density region of dangling bonds and lattice defects is formed. Conductive impurities derived from an RIE device or unspecified sources reach the damaged portion and thus enrichment occurs. The formation of the damaged portion results in an increase in drain leak current and thus the restoration needs to be performed. When hydrogen and ammonia are contained at certain levels, the restoration regarding the dangling bonds and the like and the removal and passivation of the impurities can be achieved during the growth of a regrown layer 27 described below.

Subsequently, the resist pattern Ml is removed and the wafer is cleaned. The wafer is inserted into an MOCVD apparatus and a regrown layer 27 including an electron drift layer 22 composed of undoped GaN and an electron supply layer 26 composed of undoped AlGaN is grown as shown in FIG. 6. In the growth of the undoped GaN layer 22 and undoped AlGaN layer 26, thermal cleaning is performed in an atmosphere of (NH₃+H₂), and then an organic metal material is supplied while (NH₃+H₂) is being introduced. In the thermal cleaning before the formation of the regrown layer 27 or in the formation of the regrown layer 27, the restoration regarding the damaged portion and the removal and passivation of the conductive impurities are allowed to proceed.

Subsequently, the wafer is taken out of the MOCVD apparatus. An insulating layer 9 is grown as shown in FIG. 7. A source electrode S and a drain electrode D are formed on the top surface of the epitaxial layer and the bottom surface of the GaN substrate 1, respectively, by photolithography and electron beam deposition as shown in FIG. 1.

### <Modification of Semiconductor Device in FIG. 1>

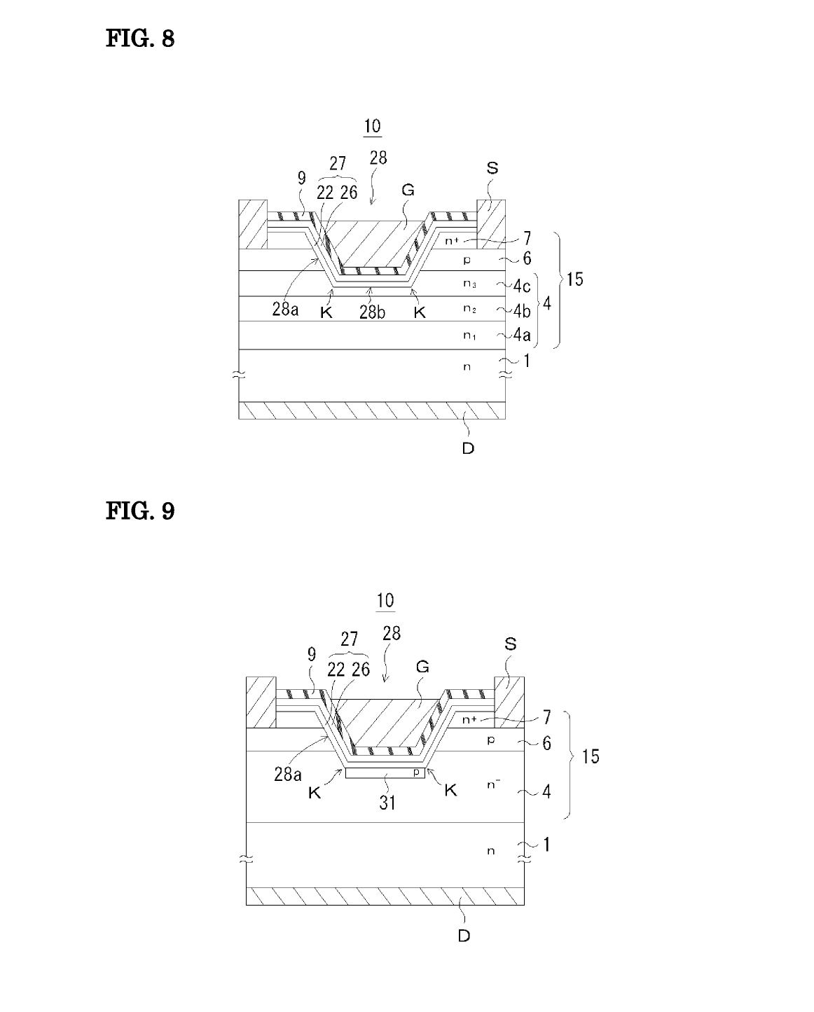

FIG. 8 shows a semiconductor device 10 according to an embodiment of the present invention, which is a modification of the first embodiment. In this modification, the n⁻-type GaN drift layer 4 is divided into three layers unlike the semiconductor device in FIG. 1. The n⁻-type GaN drift layer 4 is constituted by first GaN drift layer 4a (n-type impurity concentration n₁)/second GaN drift layer 4b (n-type impurity concentration n₂)/third GaN drift layer 4c (n-type impurity concentration n₃) formed in that order from the substrate side. In these three layers, the n-type impurity concentrations may satisfy, for example, n₃<n₂<n₁.

### Second Embodiment

FIG. 9 is a diagram showing a semiconductor device according to a second embodiment of the present invention. The feature of this embodiment is that a plate-shaped bottom p-type region 31 is disposed in the bottom portion 28b of the opening. The drift layer is formed of a single n⁻-type GaN drift layer 4. Other structures are the same as those of the semiconductor device 10 in the first embodiment (refer to FIG. 1).

The plate-shaped bottom p-type region 31 is in contact with the regrown layer 27 on the opening 28 side and forms a pn junction with the n⁻-type GaN drift layer 4 on the substrate 1 side. At the pn junction, a depletion layer is formed under the application of reverse bias voltage in the off-state and a voltage drop can be provided at the pn junction. Furthermore, a potential barrier formed at the pn junction also contributes to the voltage drop with certainty under the application of reverse bias voltage, which decreases the electric potential in a portion of the plate-shaped bottom p-type region 31 on the substrate 1 side. Consequently, the potential difference between the bottom portion 28b of the opening and the gate electrode G decreases and thus the electric field concentration in the bottom portion 28b of the opening is reduced. The electric field concentration at the corner K is also reduced with certainty.

A method for producing the semiconductor device shown in FIG. 9 will be described below. Only differences in production method between the semiconductor device shown in FIG. 9 and the semiconductor device in the first embodiment are described.
(S1) A stacked layer 15 including n⁻-type GaN drift layer 4/p-type GaN barrier layer 6/n⁺-type GaN contact layer 7 is grown in that order from the substrate 1 side.
(S2) An opening 28 is formed.
(S3) (i) A resist pattern that masks a portion other than the bottom portion 28b in the opening 28 is formed, and ion implantation with a p-type impurity such as Mg is performed so that a plate-shaped bottom p-type region 31 is formed in the bottom portion 28b.
(ii) Instead of the process (i), a resist pattern that masks a portion other than the bottom portion 28b in the opening 28 is formed, and the bottom portion 28b is etched and then the embedded growth of a plate-shaped bottom p-type region 31 is performed.

The process (i) or (ii) of (S3) is a production process unique to the semiconductor device 10 of this embodiment. After that, the same production process as that in the first embodiment is performed, that is, a step of forming a regrown layer is performed.

### <Modification 1 of Semiconductor Device in FIG. 9>

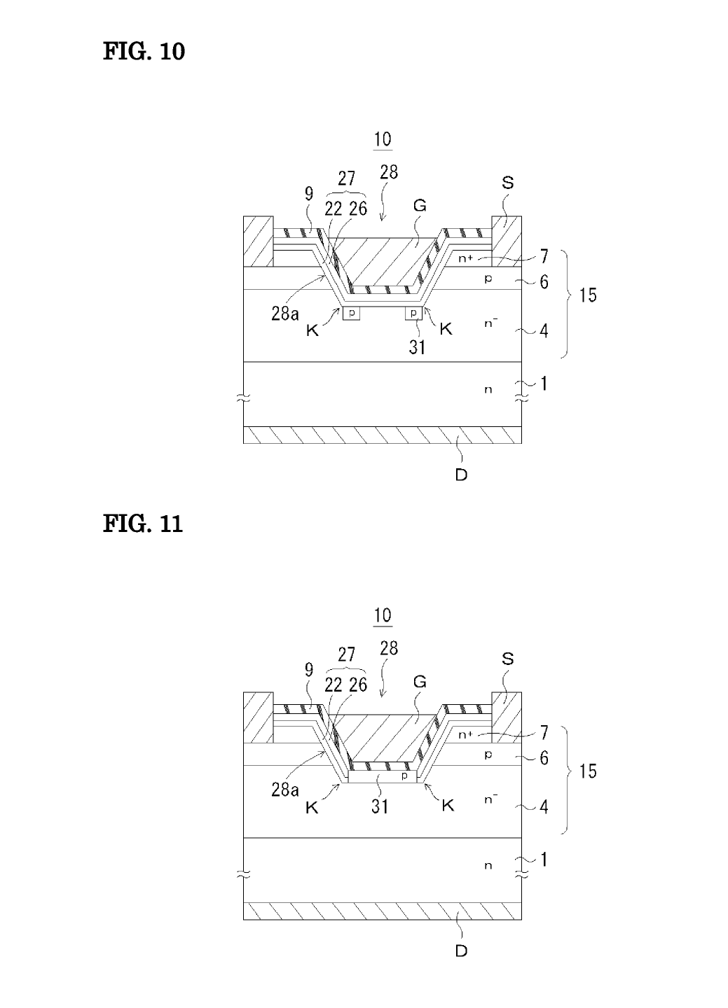

FIG. 10 shows a semiconductor device 10 of an embodiment of the present invention, which is a modification of the second embodiment. In this modification 1, the bottom p-type region 31 has a ring shape unlike the semiconductor device in FIG. 9 and is located below the regrown layer 27 in the bottom portion 28b of the opening so as to be in contact with the regrown layer 27. In particular, the bottom p-type region 31 is located near the edge of the bottom portion 28b of the opening or near the corner K in a localized manner. As described above, the corner K in the sectional view is a ridge at which the bottom portion 28b of the opening and the wall surface of the opening intersect each other. The ring-shaped bottom p-type region 31 is disposed below and along the ridge with a diameter smaller than that of the ridge. Since the opening 28 has a hexagonal shape, the ridge also forms a hexagonal shape and the bottom p-type region 31 disposed along the ridge has a hexagonal ring shape.

An effect of reducing the electric field concentration in the bottom portion of the opening using the ring-shaped bottom p-type region 31 is produced with the same mechanism as that of the bottom p-type region disposed in the semiconductor device in FIG. 9. However, in the semiconductor device 10 of the modification 1, the bottom p-type region 31 locally contributes to reducing the electric field concentration at the edge or the corner K. Therefore, the bottom p-type region 31 does not considerably contribute to reducing the electric field concentration in the center of the bottom portion 28b. However, since breakdown caused by electric field concentration occurs intensively at the corner K of the bottom portion 28b of the opening, the breakdown voltage characteristics can be effectively improved. In addition, since the bottom p-type region 31 is locally disposed below and inside of the corner M as described above, the bottom p-type region 31 is less prone to becoming an obstacle to electrons that flow into the n⁻-type GaN drift layer 4 from the electron drift layer 22. This is a preferred structure for achieving low on-resistance.

In short, in the semiconductor device 10 in FIG. 10, the bottom p-type region 31 effectively contributes to reducing the electric field concentration at the corner K of the bottom portion 28b of the opening while at the same time low on-resistance can be maintained.

A method for producing the semiconductor device 10 in FIG. 10 is the same as the method for producing the semiconductor device in FIG. 9, except that the shape of the bottom p-type region 31 is changed, which is a minor change.

### <Modification 2 of Semiconductor Device in FIG. 9>

FIG. 11 shows a semiconductor device 10 of an embodiment of the present invention, which is a modification of the second embodiment. In this modification, the bottom p-type region 31 is a regrown layer bottom region obtained by converting the regrown layer into a p-type regrown layer, unlike the semiconductor device in FIG. 9. Therefore, the regrown layer bottom region 31 in this modification 2 has a structure and effects similar to those of the bottom p-type region 31 of the semiconductor device in FIG. 9.

Points to keep in mind are as follows. The regrown layer bottom region 31 in the modification 2 is obtained by converting the regrown layer into a p-type regrown layer. If the regrown layer bottom region 31 is formed in the entire bottom portion 28b, the regrown layer bottom region 31 obstructs the flow of electrons. Therefore, the diameter of the regrown layer bottom region 31 is preferably set to be smaller than that of the bottom portion 28b of the opening in order to maintain low on-resistance.

The production method has the following difference, which is not significant difference. The bottom p-type regions 31 in the semiconductor devices 10 in FIGS. 9 and 10 are each formed in the bottom portion 28b of the opening in a step prior to the step of forming the regrown layer 27. The regrown layer bottom region 31 in the semiconductor device 10 of this modification 2 is formed by forming the regrown layer 27, then forming a resist pattern that covers a portion other than the bottom portion of the regrown layer, and performing ion implantation with a p-type impurity to convert the bottom portion of the regrown layer into a p-type bottom portion. For example, Mg can be used as the p-type impurity.

### Examples

Regarding the semiconductor device of the first embodiment shown in FIG. 1, the reduction in the electric field concentration at the edge of the bottom portion of the opening 28 was investigated using a computer simulation. The structure of the semiconductor device 10 is as follows.
<First GaN drift layer 4a>: thickness 5 μm, all test specimens had the same n-type impurity concentration of 1×10¹⁶ (1E16) cm⁻³
<Second GaN drift layer 4b>: thickness 0.3 μm, n-type impurity concentration (A1) 1×10¹⁴ (1E14) cm⁻³, (A2) 1×10¹⁵ (1E15) cm⁻³, (A3) 1×10¹⁶ (1E16) cm⁻³, (B1) 5×10¹⁶ (5E16) cm⁻³, (B2) 1×10¹⁷ (1E17) cm⁻³

In the test specimens (A1) to (A3), the n-type impurity concentration in the second GaN drift layer 4b is lower than the n-type impurity concentration in the first GaN drift layer 4a. The test specimens (A1) to (A3) are treated as Invention Examples A1 to A3. In a strict sense, the test specimen (A3) having an n-type impurity concentration of 1×10¹⁶ (1E16) cm⁻³ cannot be treated as Invention Example. However, the test specimen (A3) was treated as Invention Example by interpreting the n-type impurity concentration in the second GaN drift layer 4b as a concentration only slightly lower than the n-type impurity concentration in the first GaN drift layer 4a. Other test specimens are treated as Comparative Examples (B1) and (B2). In Comparative Examples B1 and B2, the n-type impurity concentration in the second GaN drift layer 4b is higher than that in the first GaN drift layer 4a.

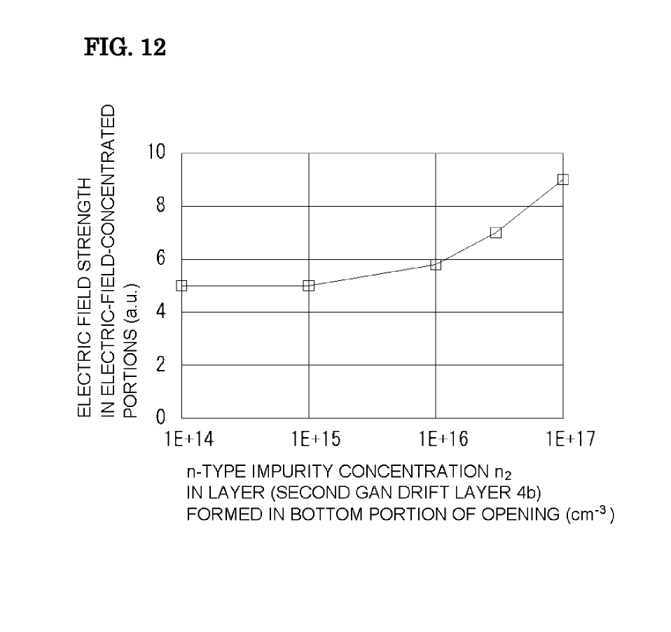

The simulation was evaluated by determining the electric field strength (arbitrary unit) at the corner K of the bottom portion 28b of the opening. The electric field strength of Invention Example A1 is assumed to be 5 (referred to as a reference value), and the electric field strengths of other test specimens are shown as relative values. FIG. 12 shows the results.

Referring to FIG. 12, the test specimen of Comparative Example B2 has an electric field strength of 9, which is almost twice the reference value of 5, because the second GaN drift layer 4b has a high n-type impurity concentration. By decreasing the n-type impurity concentration, the electric field strength is decreased to about 7 (1.4 times the reference value) in Comparative Example B1. In Invention Example A3 in which the n-type impurity concentration is further decreased, the electric field strength is decreased to a little less than 6 (1.2 times the reference value). Furthermore, when the n-type impurity concentration is decreased to 1×10¹⁵ (1E15) cm⁻³ or less as in Invention Example A2 or A1, the electric field strength is decreased to about 5 (reference value).

It was confirmed from the simulation results that the electric field concentration in the bottom portion 28b of the opening could be reduced by decreasing the n-type impurity concentration in the second GaN drift layer 4b. Accordingly, the n⁻-type GaN drift layer 4 is divided into two layers and the n-type impurity concentration in the second GaN drift layer 4b that forms the bottom portion 28b of the opening is set to be lower than the n-type impurity concentration in the first GaN drift layer 4a located below the second GaN drift layer 4b, whereby the electric field concentration in the bottom portion 28b of the opening can be reduced.

The structures disclosed in the above embodiments of the present invention are mere examples and the scope of the present invention is not limited to these embodiments. The scope of the present invention is defined by the appended claims, and all changes that fall within the scope of the claims and the equivalence thereof are therefore embraced by the claims.

### INDUSTRIAL APPLICABILITY

According to the semiconductor device or the like of the present invention, in a vertical semiconductor device having an opening, the breakdown voltage characteristics in the off-state can be improved by disposing an impurity adjustment layer that promotes a voltage drop from the drain electrode side to the gate electrode side in the potential distribution in the off-state. The breakdown voltage characteristics in the off-state can be stably improved by employing a simple structure in which, for example, the impurity adjustment layer is formed by dividing a drift layer into two layers and setting the n-type impurity concentration of a drift layer that forms a bottom portion of an opening to be low.

1. A vertical semiconductor device including a GaN-based stacked layer having an opening,
the GaN-based stacked layer including n-type GaN-based drift layer/p-type GaN-based barrier layer/n-type GaN-based contact layer in that order to the top layer side, the opening extending from a top layer and reaching the n-type GaN-based drift layer, the semiconductor device comprising:
a regrown layer located so as to cover a wall surface of the opening, the regrown layer including an electron drift layer and an electron supply layer;
a source electrode that is in contact with the n-type GaN-based contact layer and the regrown layer;
a drain electrode located so as to face the source electrode with the GaN-based stacked layer sandwiched therebetween;
a gate electrode located on the regrown layer; and
a semiconductor impurity adjustment region disposed in a bottom portion of the opening,
wherein the impurity adjustment region is a region that promotes a potential drop from the drain electrode side to the gate electrode side in a potential distribution in an off-state.

2. The semiconductor device according to claim 1, wherein the impurity adjustment region is a region formed by dividing the n-type GaN-based drift layer into a plurality of layers and setting an n-type impurity concentration in one of said plurality of layers to be lower than those in other layers.

3. The semiconductor device according to claim 2, wherein the n-type GaN-based drift layer is divided into a second n-type drift layer that forms the bottom portion of the opening and a first n-type drift layer located on the drain electrode side of the second n-type drift layer, and an n-type impurity concentration in the second n-type drift layer is set to be lower than that in the first n-type drift layer.

4. The semiconductor device according to claim 1, wherein the impurity adjustment region is a bottom p-type region disposed in the bottom portion of the opening so as not to obstruct flow of electrons from the regrown layer, and a pn junction is formed between the bottom p-type region and the n-type GaN-based drift layer located below the bottom p-type region.

5. The semiconductor device according to claim 4, wherein the bottom p-type region is any one of (1) a plate-shaped bottom region having a plate-like shape and located below the regrown layer that covers the bottom portion of the opening, (2) a ring-shaped bottom region located below the regrown layer that covers the bottom portion of the opening and only at an edge of the bottom portion, and (3) a regrown layer bottom region formed by doping the regrown layer that covers the bottom portion of the opening with a p-type impurity.

6. A method for producing a vertical semiconductor device including a GaN-based stacked layer having an opening, the method comprising:
a step of forming a GaN-based stacked layer including n-type GaN-based drift layer/p-type GaN-based barrier layer/n-type GaN-based contact layer in that order to the top layer side;
a step of forming an opening that extends from the n-type GaN-based contact layer and reaches the n-type GaN-based drift layer; and
a step of forming a regrown layer so as to cover a wall surface and a bottom portion of the opening, the regrown layer including an electron drift layer and an electron supply layer,
wherein, in the step of forming the GaN-based stacked layer, the n-type GaN-based drift layer is formed by successively growing a plurality of layers, and an n-type impurity concentration in one of said plurality of layers is set to be lower than those in other layers.

7. The method for producing a semiconductor device according to claim 6, wherein, in the step of forming the GaN-based stacked layer, when the n-type GaN-based drift layer is grown, a first n-type drift layer is grown and then a second n-type drift layer is grown on the first n-type drift layer, and an n-type impurity concentration in the second n-type drift layer is set to be lower than that in the first n-type drift layer.

8. A method for producing a vertical semiconductor device including a GaN-based stacked layer having an opening, the method comprising:
a step of forming a GaN-based stacked layer including n-type GaN-based drift layer/p-type GaN-based barrier layer/n-type GaN-based contact layer in that order to the top layer side;
a step of forming an opening that extends from the n-type GaN-based contact layer and reaches the n-type GaN-based drift layer;
a step of forming a regrown layer so as to cover a wall surface and a bottom portion of the opening, the regrown layer including an electron drift layer and an electron supply layer; and
a step of forming a resist pattern that covers a portion other than a bottom portion of the regrown layer and performing ion implantation with a p-type impurity to convert the bottom portion of the regrown layer into a p-type bottom portion.

9. The method for producing a semiconductor device according to claim 8, wherein, before the step of forming the regrown layer and after the opening is formed, a resist pattern that covers a portion other than the bottom portion of the opening is formed and then ion implantation with a p-type impurity is performed in the bottom portion of the opening to form a bottom p-type region, or the bottom portion of the opening is removed by etching and embedded growth of a p-type layer is performed in the bottom portion to form a bottom p-type region; then the regrown layer is formed; and the following step of performing ion implantation with a p-type impurity is not conducted.
